(19) United States
(12) Patent Application Publication
(10) Pub. No.: US 2025/0324881 A1
(43) Pub. Date: Oct. 16, 2025

(54) DISPLAY DEVICE AND METHOD OF MANUFACTURING THE SAME

(71) Applicant: Samsung Display Co., LTD., Yongin-si (KR)

(72) Inventors: Il Ha SONG, Yongin-si (KR); Nam Su KANG, Yongin-si (KR)

(21) Appl. No.: 18/828,802

(22) Filed: Sep. 9, 2024

(30) Foreign Application Priority Data
Apr. 11, 2024 (KR) 10-2024-0048638

(51) Int. Cl. H10K 59/00; H10K 50/15; H10K 50/17; H10K 59/12; H10K 59/35; H10K 101/30; H10K 102/00

(52) U.S. Cl. CPC H10K 59/771; H10K 50/156; H10K 50/17; H10K 59/1201; H10K 59/35; H10K 2101/30; H10K 2102/351

(57) ABSTRACT

A display device includes: a pixel circuit layer on a substrate; anodes on the pixel circuit layer and spaced apart from each other; hole injection layers respectively on the anodes; hole transport layers respectively on the hole injection layers; light emitting layers respectively on the hole transport layers; and a common layer on the light emitting layers.

### CROSS-REFERENCE TO RELATED APPLICATION

The present application claims priority to and the benefit of Korean Patent Application No. 10-2024-0048638, filed on Apr. 11, 2024, in the Korean Intellectual Property, the entire disclosure of which is incorporated herein by reference.

### BACKGROUND

### 1. Field

Aspects of some embodiments of the present disclosure relate to a display device and a method of manufacturing a display device.

### 2. Description of the Related Art

With the development of information technologies, the importance of a display device that provide a connection medium between users and information has increased. Accordingly, display devices such as liquid crystal display devices and organic light emitting display devices are increasingly used.

The above information disclosed in this Background section is only for enhancement of understanding of the background and therefore the information discussed in this Background section does not necessarily constitute prior art.

### SUMMARY

Aspects of some embodiments of the present disclosure include a method of manufacturing a display device, which may relatively reduce a process margin, and a high-resolution display device manufactured according to the method.

According to some embodiments of the present disclosure, a display device includes: a substrate, a pixel circuit layer on the substrate, anodes on the pixel circuit layer while being spaced apart from each other, hole injection layers respectively on the anodes, hole transport layers respectively on the hole injection layers, light emitting layers respectively on the hole transport layers, and a common layer on the light emitting layers.

According to some embodiments, the anodes may include a first anode, a second anode, and a third anode. The hole injection layers may include a first hole injection layer on the first anode, a second hole injection layer on the second anode, and a third hole injection layer on the third anode.

According to some embodiments, the hole transport layers may include a first hole transport layer on the first hole injection layer, a second transport layer on the second hole injection layer, and a third hole transport layer on the third hole injection layer.

According to some embodiments, a thicknesses of the first hole transport layer, the second hole transport layer, and the third hole transport layer may be different from one another.

According to some embodiments, a thickness of the first hole transport layer may be greater than a thickness of the second hole transport layer, and the thickness of the second hole transport layer may be greater than a thickness of the third hole transport layer.

According to some embodiments, a thickness of the first hole transport layer may be in a range of 1950 to 2300 Å, a thickness of the second hole transport layer may be in a range of 1350 to 1700 Å, and a thickness of the third hole transport layer may be in a range of 1150 to 1400 Å.

According to some embodiments, the hole transport layers may be made of the same material.

According to some embodiments, the hole transport layers may be made of different materials.

According to some embodiments, a HOMO energy level of the hole transport layers may be −5.1 eV or higher.

According to some embodiments, the light emitting layers may include a first light emitting layer on the first hole transport layer and emits light of a first color, a second light emitting layer on the second hole transport layer and emits light of a second color, and a third light emitting layer on the third hole transport layer and emits light of a third color. According to some embodiments, the first hole transport layer may control resonance of the light of the first color, which is emitted from the first light emitting layer, and the second hole transport layer may control resonance of the light of the second color, which is emitted from the second light emitting layer.

According to some embodiments, the display device may further include a first light emitting auxiliary layer between the first hole transport layer and the first light emitting layer, a second light emitting auxiliary layer between the second hole transport layer and the second light emitting layer, and a third light emitting auxiliary layer between the third hole transport layer and the third light emitting layer.

According to some embodiments, the common layer may include a buffer layer on the light emitting layers, an electron transport layer on the buffer layer, a cathode on the electron transport layer, and a capping layer on the cathode.

According to some embodiments of the present disclosure, a method of manufacturing a display device includes: forming anodes on a pixel circuit layer on a substrate while being spaced apart from each other, respectively forming hole injection layers on the anodes, using a fine silicon mask and a hole injection source, respectively forming hole transport layers on the hole injection layers, using the fine silicon mask and hole transport sources, respectively forming light emitting layers on the hole transport layers, using the fine silicon mask and light emitting sources, and forming a common layer on the light emitting layers, using an open mask.

According to some embodiments, an incident angle at which the hole injection source, the hole transport sources, and the light emitting sources pass through the fine silicon mask may be in a range of 80 to 90 degrees.

According to some embodiments, the hole injection source, the hole transport sources, and the light emitting sources may be point sources in a standstill state.

According to some embodiments, a width of the hole injection layers, the hole transport layers, and the light emitting layers, which overlap with a shadow area of the substrate, may be 0.2 μm or less.

According to some embodiments, a width of an opening of the fine silicon mask may be 0.5 μm or less.

According to some embodiments, a thicknesses of the hole transport layers may be different from one another.

According to some embodiments, the hole transport sources may be made of the same material.

According to some embodiments, the hole transport sources may be made of different materials.

### BRIEF DESCRIPTION OF THE DRAWINGS

The above and other aspects and features of embodiments according to the present disclosure will become more apparent by describing, in further detail, aspects of some embodiments thereof with reference to the accompanying drawings, in which:

FIG. 1 is a block diagram of a display device according to some embodiments.

FIG. 2 is a block diagram of a sub-pixel according to some embodiments.

FIG. 3 is a circuit diagram of a sub-pixel according to some embodiments.

FIG. 4 is a plan view of a display panel according to some embodiments.

FIG. 5 is a view of a pixel according to some embodiments.

FIG. 6 is a view of a deposition process according to some embodiments.

FIG. 7 is a view of a deposition process according to some embodiments.

FIG. 8 is a view of a pixel according to some embodiments.

FIG. 9 is a view of a pixel according to some embodiments.

FIG. 10 is a block diagram of a display system according to some embodiments.

FIG. 11 is a perspective view of an application example of the display system of FIG. 10 according to some embodiments.

FIG. 12 is a view of a head-mounted display device of FIG. 11, which is worn by a user according to some embodiments.

### DETAILED DESCRIPTION

Hereinafter, aspects of some embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to disclosed embodiments described herein, but may be embodied in various different forms. Rather, the disclosed embodiments described herein are provided to more thoroughly and more completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, aspects of some embodiments of the present disclosure are described here with reference to schematic diagrams of some embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Hereinafter, aspects of some embodiments of the present disclosure will be described in more detail with reference to the accompanying drawings.

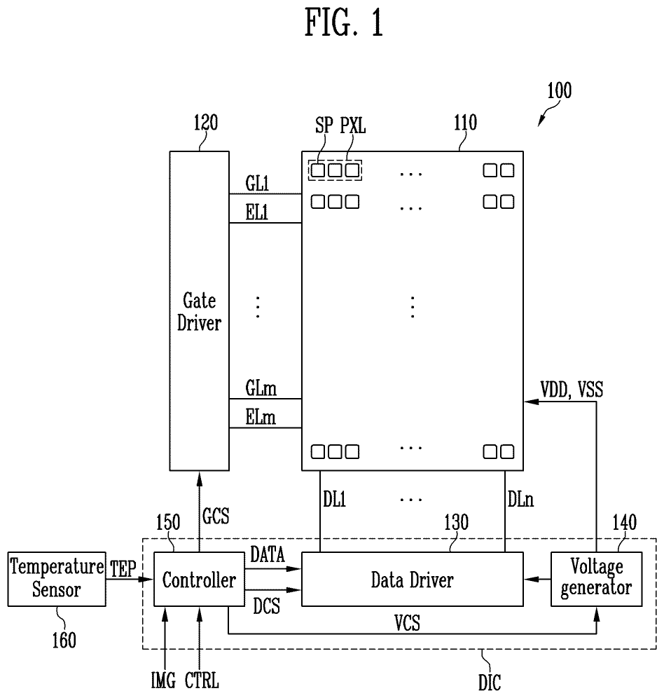

FIG. 1 is a block diagram of a display device according to some embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. According to some embodiments, the gate control signal GCS may include a start signal indicating a start of each frame, a horizontal synchronization signal for outputting gate signals in synchronization with timings at which data signals are applied, and the like.

According to some embodiments, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be located at one side of the display panel 110. However, embodiments according to the present disclosure are not limited thereto. For example, the gate driver 120 may be divided into two or more drivers which are physically and/or logically divided, and these drivers may be located at one side of the display panel 110 and the other side of the display panel 110, which is opposite to the one side. As such, in some embodiments, the gate driver 120 may be arranged in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. According to some embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the first to nth data lines DL1 to DLm. Accordingly, corresponding sub-pixels SP may generate light corresponding to the data signals. Accordingly, images may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. According to some embodiments, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a reference voltage (e.g., a set or predetermined reference voltage) may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. According to some embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. According to some embodiments, at least one of the data driver 130, the voltage generator 140, or the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. According to some embodiments, the temperature sensor 160 may be arranged to be adjacent to the display panel 110 and/or the driver integrated circuit DIC.

The controller 150 may control various operations of the display device 100 in response to the temperature data TEP. According to some embodiments, the controller 150 may adjust the luminance of an image output from the display device 100 in response to the temperature data TEP. For example, the controller 150 may control components such as the data driver 130 and/or the voltage generator 140, thereby adjusting data signals and the first and second power voltages VDD and VSS.

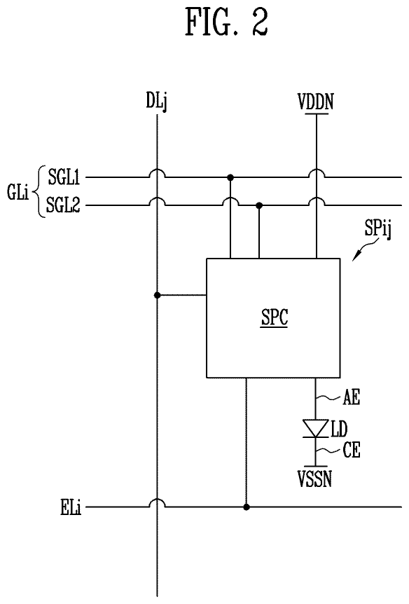

FIG. 2 is a block diagram of a sub-pixel according to some embodiments. In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 is illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode AE of the light emitting element LD may be connected to the first power voltage node VDDN through the sub-pixel circuit SPC, and a cathode CE of the light emitting element LD may be connected to the second power voltage node VSSN. For example, the anode AE of the light emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. According to some embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. According to some embodiments, the ith emission control line ELi may include one or more sub-emission control lines. When the ith emission control line ELi includes two or more sub-emission control lines, the sub-pixel circuit SPC may operate in response to emission control signals receives through the corresponding emission control lines.

The sub-pixel circuit SPC may receive a data signal through the jth data line DLj. The sub-pixel circuit SPC may store a voltage corresponding to the data signal in response to at least one of the gate signals received through the first and/or second sub-gate lines SGL1 and/or SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

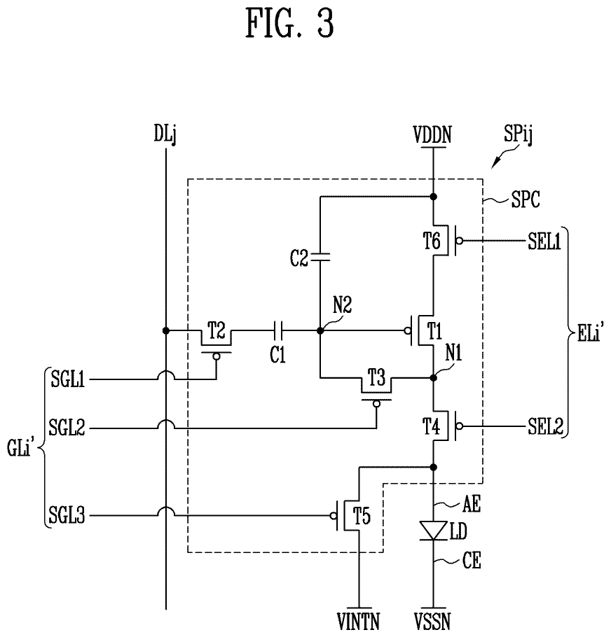

FIG. 3 is a circuit diagram of a sub-pixel according to some embodiments. Although FIG. 3 illustrates various components in a sub-pixel, embodiments according to the present disclosure are not limited thereto, and according to some embodiments, the sub-pixel may include additional components or fewer components without departing from the spirit and scope of embodiments according to the present disclosure.

Referring to FIG. 3, a sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode AE of the light emitting element LD and an initialization voltage node VINTN. The initialization voltage node VINTN may be configured to transfer an initialization voltage. According to some embodiments, the initialization voltage may be provided by the voltage generator 140 shown in FIG. 1. According to some embodiments, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments according to the present disclosure are not limited thereto. The sub-pixel circuit SPC may be implemented as any one of various types of circuits each including a plurality of transistors and one or more capacitors. For example, the sub-pixel circuit SPC may include two transistors and one capacitor. In accordance with embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments according to the present disclosure are not limited thereto. For example, at least one of the first to sixth transistors T1 to T6 may be replaced with an N-type transistor.

According to some embodiments, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode AE, a cathode CE, and a light emitting layer. The light emitting layer may be located between the anode AE and the cathode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

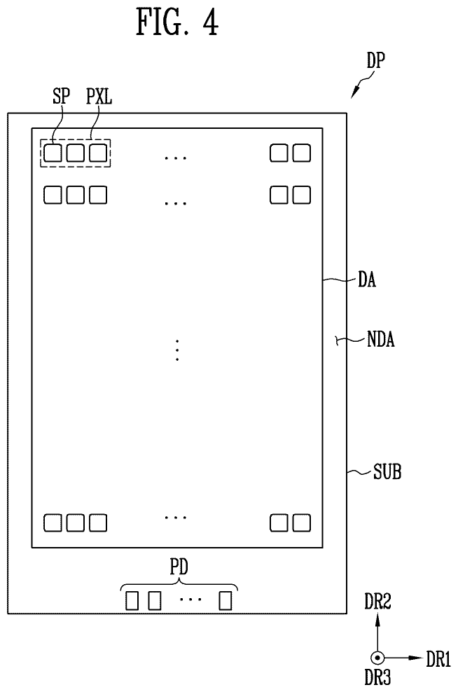

FIG. 4 is a plan view of a display panel according to some embodiments.

Referring to FIG. 4, the display panel DP of the display panel 110 shown in FIG. 1 may include a display area DA and a non-display area NDA. The display panel DP may display images through the display area DA. The non-display area NDA may be located at the periphery of (e.g., surrounding or outside a footprint of) the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. The sub-pixels SP having a relatively high degree of integration may be required. In order to increase the integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The sub-pixels SP may be located in the display area DA on the substrate SUB. The sub-pixels SP may be arranged in a matrix form along a first direction DR1 and a second direction DR2 intersecting the first direction DR1. However, embodiments according to the present disclosure are not limited thereto. For example, the sub-pixels SP may be arranged in a zigzag form along the first direction DR1 and the second direction DR2. For example, the sub-pixels SP may be arranged in a PENTILET form or arrangement. The first direction DR1 may be a row direction, and the second direction DR2 may be a column direction.

Two or more sub-pixels among the sub-pixels SP may constitute one pixel PXL.

A component for controlling the sub-pixels SP may be located in the non-display area NDA on the substrate SUB. For example, lines connected to the sub-pixels SP, such as the first to mth gate lines GL1 to GLm and the first to nth data lines DL1 to DLn, which are shown in FIG. 1, may be located in the non-display area NDA.

At least one of the gate driver 120, the data driver 130, the voltage generator 140, the controller 150, or the temperature sensor 160, which are shown in FIG. 1, may be integrated in the non-display area NDA of the display panel DP. According to some embodiments, the gate driver 120 shown in FIG. 1 is mounted on the display panel DP, and may be located in the non-display area NDA. According to some embodiments, the gate driver 120 may be implemented as an integrated circuit distinguished from the display panel DP. According to some embodiments, the temperature sensor 160 may be located in the non-display area NDA to sense a temperature of the display panel DP.

The pads PD may be located in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). According to some embodiments, voltages and signals, which are necessary for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

According to some embodiments, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

According to some embodiments, the display area DA may have various shapes. The display area DA may have a closed-loop shape including linear sides and/or curved sides. For example, the display area DA may have shapes such as a polygon, a circle, a semicircle, and an ellipse.

According to some embodiments, the display panel DP may have a flat display surface. According to some embodiments, the display panel DP may at least partially have a round display surface. According to some embodiments, the display panel DP may be bendable, foldable or rollable. The display panel DP and/or the substrate SUB may include materials having flexibility.

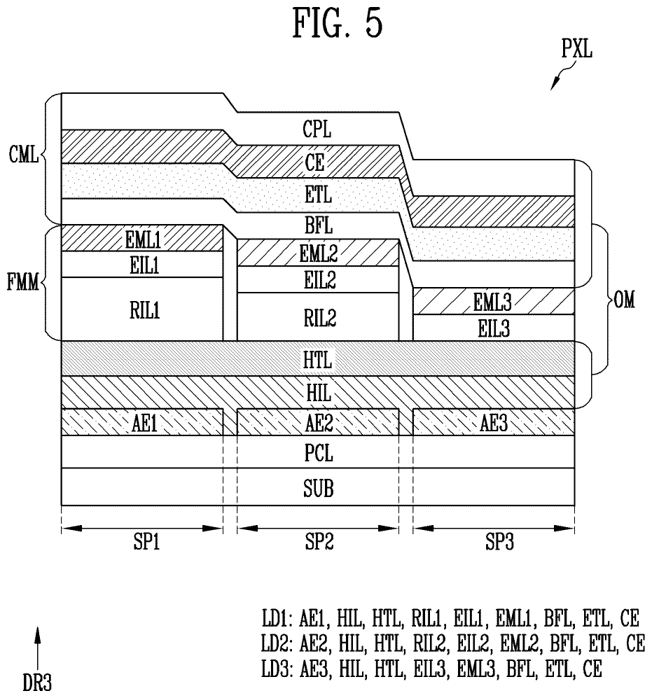

FIG. 5 is a view of a pixel according to some embodiments.

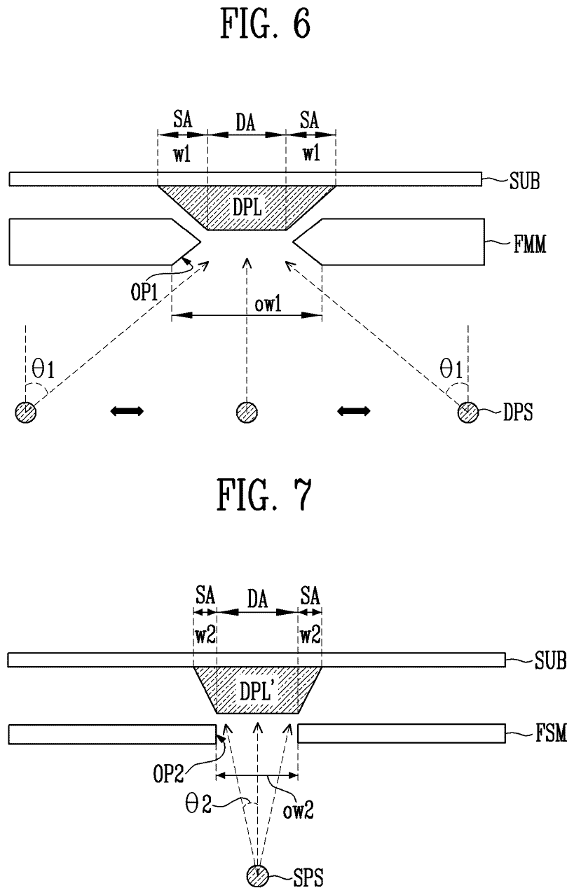

In FIG. 5, a pixel PXL manufactured according to a deposition process shown in FIG. 6, which will be described in more detail later, is illustrated as an example.

Referring to FIG. 5, the pixel PXL may include first to third sub-pixels SP1 to SP3. Each of the first to third sub-pixels SP1 to SP3 may generate light of one of various colors such as red, green, blue, cyan, magenta, and yellow. Hereinafter, for convenience of description, it is assumed that the first sub-pixel SP1 is configured to generate light of a red color, the second sub-pixel SP2 is configured to generate light of a green color, and the third sub-pixel SP3 is configured to generate light of a blue color. However, embodiments according to the present disclosure are limited thereto. For example, the pixel PXL may further include a sub-pixel configured to generate light of a white color in addition to the first to third sub-pixels SP1 to SP3.

A substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. However, embodiments according to the present disclosure are not limited thereto. For example, the substrate SUB may include a glass substrate or a polyimide (PI) substrate.

A pixel circuit layer PCL may be located on the substrate SUB. The substrate SUB and/or the pixel circuit layer PCL may include insulating layers and conductive patterns located between the insulating layers. The conductive patterns of the pixel circuit layer PCL may serve as at least some of circuit elements, lines, and the like. The conductive patterns may include copper, but embodiments according to the present disclosure are not limited thereto.

The circuit elements may include a sub-pixel circuit SPC (see FIG. 2) of each of the first to third sub-pixels SP1 to SP3. The sub-pixel circuit SPC may include transistors and one or more capacitors. Each transistor may include a semiconductor portion including a source region, a drain region, and a channel region, and a gate electrode overlapping with the semiconductor portion. According to some embodiments, when the substrate SUB is provided as a silicon substrate, the semiconductor portion may be included in the substrate SUB, and the gate electrode may be included as a conductive pattern of the pixel circuit layer PCL in the pixel circuit layer PCL. According to some embodiments, when the substrate SUB is provided as a glass substrate or a PI substrate, the semiconductor portion and the gate electrode may be included in the pixel circuit layer PCL.

The lines of the pixel circuit layer PCL may include signal lines, e.g., a gate line, an emission control line, a data line, and the like, which are connected to each of the first to third sub-pixels SP1 to SP3. The lines may further include a line connected to the first power voltage node VDDN shown in FIG. 2. The lines may further include a line connected to the second power voltage node VSSN shown in FIG. 2.

First to third anodes AE1 to AE3 may be located on the pixel circuit layer PCL. The first to third anodes AE1 to AE3 may be spaced apart from each other, and be respectively included in the first to third sub-pixels SP1 to SP3. The first anode AE1 may receive an electrical signal for driving the first sub-pixel SP1 from the pixel circuit layer PCL. The second anode AE2 may receive an electrical signal for driving the second sub-pixel SP2 from the pixel circuit layer PCL. The third anode AE3 may receive an electrical signal for driving the third sub-pixel SP3 from the pixel circuit layer PCL.

The first to third anodes AE1 to AE3 may include at least one of indium tin oxide (ITO), indium zinc oxide (IZO), zinc oxide (ZnOₓ), indium gallium zinc oxide (IGZO), indium tin zinc oxide (ITZO), titanium (Ti), titanium nitride (TiN), tantalum nitride (TaN), silver (Ag), magnesium (Mg), aluminum (AI), or nickel (Ni). However, embodiments according to the present disclosure are not limited thereto.

A hole injection layer HIL may be located on the first to third anodes AE1 to AE3. For example, the hole injection layer HIL may be located directly on the first to third anodes AE1 to AE3 to be in contact with the first to third anodes AE1 to AE3. The hole injection layer HIL may be located on the pixel circuit layer PCL to cover the first to third anodes AE1 to AE3.

The hole injection layer HIL may be provided as a single layer. For example, the hole injection layer HIL may be entirely provided in the form of a single layer throughout the first to third sub-pixels SP1 to SP3.

The hole injection layer HIL may include a triazine compound. For example, the hole injection layer HIL may include at least one of the following first to eighth triazine compounds TA1 to TA8.

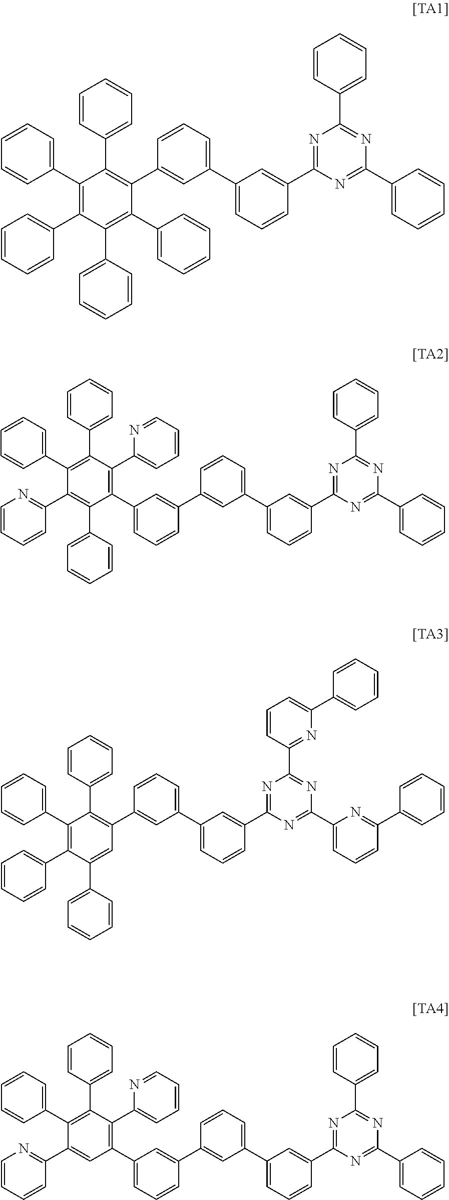 [SMILES: c1ccc(-c2nc(-c3ccccc3)nc(-c3cccc(-c4cccc(-c5c(-c6ccccc6)c(-c6ccccc6)c(-c6ccccc6)c(-c6ccccc6)c5-c5ccccc5)c4)c3)n2)cc1 ; c1ccc(-c2nc(-c3ccccc3)nc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)n2)cc1 ; c1ccc(-c2cccc(-c3nc(-c4cccc(-c5cccc(-c6cc(-c7ccccc7)c(-c7ccccc7)c(-c7ccccc7)c6-c6ccccc6)c5)c4)nc(-c4cccc(-c5ccccc5)n4)n3)n2)cc1 ; c1ccc(-c2nc(-c3ccccc3)nc(-c3cccc(-c4cccc(-c5cccc(-c6cc(-c7ccccn7)c(-c7ccccc7)c(-c7ccccc7)c6-c6ccccn6)c5)c4)c3)n2)cc1]

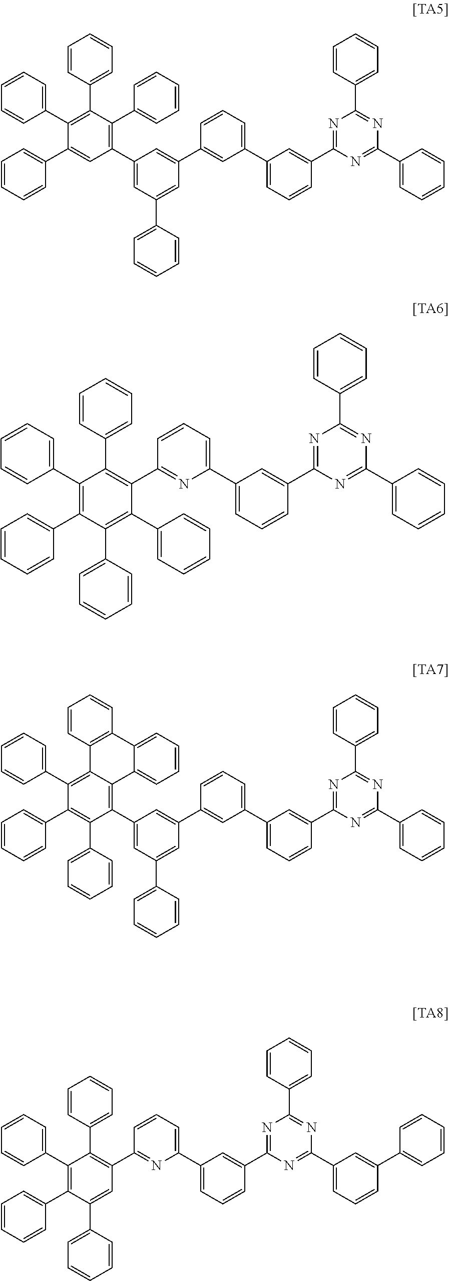

The hole injection layer HIL may include a pyrimidine compound. For example, the hole injection layer HIL may include at least one of the following first to eighth pyrimidine compounds P1 to P8.

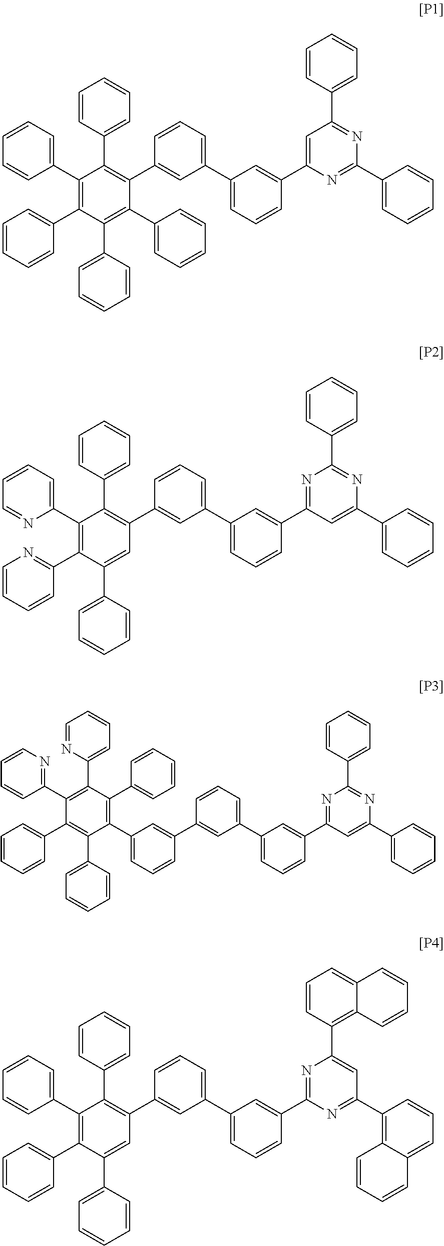 [SMILES: c1ccc(-c2cc(-c3cccc(-c4cccc(-c5c(-c6ccccc6)c(-c6ccccc6)c(-c6ccccc6)c(-c6ccccc6)c5-c5ccccc5)c4)c3)nc(-c3ccccc3)n2)cc1 ; c1ccc(-c2cc(-c3cccc(-c4cccc(-c5cc(-c6ccccc6)c(-c6ccccn6)c(-c6ccccn6)c5-c5ccccc5)c4)c3)nc(-c3ccccc3)n2)cc1 ; c1ccc(-c2cc(-c3cccc(-c4cccc(-c5cccc(-c6c(-c7ccccc7)c(-c7ccccc7)c(-c7ccccn7)c(-c7ccccn7)c6-c6ccccc6)c5)c4)c3)nc(-c3ccccc3)n2)cc1 ; c1ccc(-c2cc(-c3cccc(-c4cccc(-c5nc(-c6cccc7ccccc67)cc(-c6cccc7ccccc67)n5)c4)c3)c(-c3ccccc3)c(-c3ccccc3)c2-c2ccccc2)cc1]

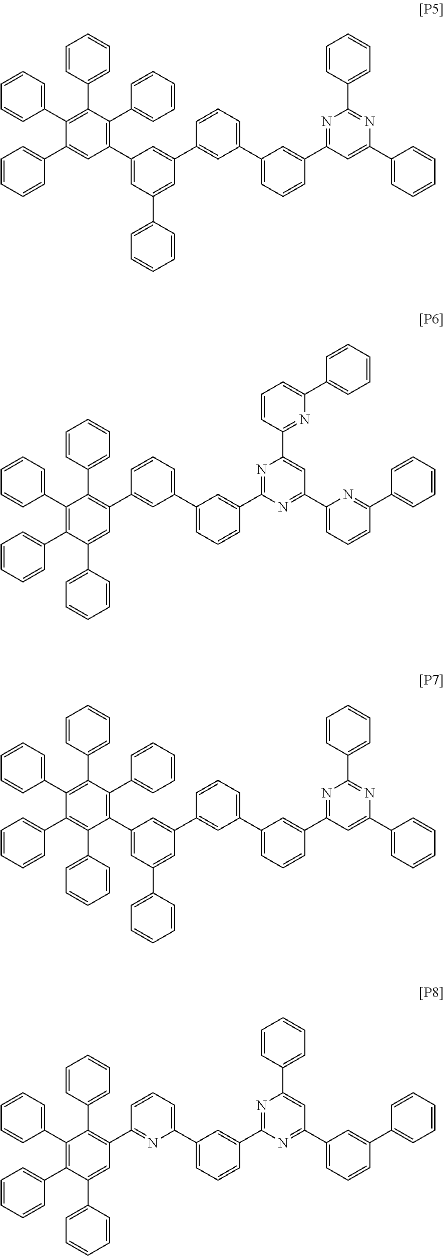

Hereinafter, for convenience of description, it is assumed that the hole injection layer HIL includes a triazine compound or a pyrimidine compound.

A Highest Occupied Molecular Orbital (HOMO) energy level of the hole injection layer HIL may be −6.3 to −5 eV. When the MOMO energy level of the hole injection layer HIL satisfies the above-described range, holes may be stably injected into the hole injection layer HIL from the first to third anodes AE1 to AE3. In other words, the stability of hole injection characteristics may increase.

A dipole moment of the hole injection layer HIL may be 1 to 6 D (debye). When the dipole moment of the hole injection layer HIL satisfies the above-described range, holes may be rapidly injected into the hole injection layer HIL from the first to third anodes AE1 to AE3. In other words, the efficiency of hole injection characteristics may increase.

A hole transport layer HTL may be located on the hole injection layer HIL. The hole transport layer HTL may be entirely provided throughout the first to third sub-pixels SP1 to SP3.

The hole injection layer HTL may include at least one of a carbazole derivative such as N-phenylcarbazole or polyvinylcarbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(1-naphthyl)-N,N′-diphenylbenzidine (NPB), N,N′-di(naphthalene-I-yl)-N, N′-diphenyl-benzidine (TAPC), 4,4′-bis[N,N′-(3-tolyl)amino]-3,3′-dimethylbiphenyl (HMTPD), 1,3-bis(N-carbazollyl)benzene (mCP), or 9-(4-tert-butylphenyl)-3,6-bis(triphenylsilyl)-9H-carbazone (CzSi). However, embodiments according to the present disclosure are not limited thereto.

First and second resonance auxiliary layers RIL1 and RIL2 may be located on the hole transport layer HTL. The first resonance auxiliary layer RIL1 may be included in the first sub-pixel SP1. The first resonance auxiliary layer RIL1 may function to control resonance of light of a red color, which is generated in a first light emitting layer EML1. The second resonance auxiliary layer RIL2 may be included in the second sub-pixel SP2. The second resonance auxiliary layer RIL2 may function to control resonance of light of a green color, which is generated in a second light emitting layer EML2. The first and second resonance auxiliary layers RIL1 and RIL2 may have different thicknesses to control resonance of lights of different colors. A thickness may be a length measured in a third direction DR3 (or thickness direction). For example, a thickness of the first resonance auxiliary layer RIL1 may be greater than a thickness of the second resonance auxiliary layer RIL2.

First and second light emitting auxiliary layers EIL1 and EIL2 may be located on the first and second resonance auxiliary layers RIL1 and RIL2, respectively. A third light emitting auxiliary layer EIL3 may be located on the hole transport layer HTL. The third light emitting auxiliary layer EIL3 may be included in the third sub-pixel SP3. Unlike the first and second sub-pixels SP1 and SP2, the third sub-pixel SP3 may not include any layers such as the first and second resonance auxiliary layers RIL1 and RIL2. The first light emitting auxiliary layer EIL1 may function to relatively improve the light emission efficiency (or red light emission efficiency) of the first light emitting layer EML1 by adjusting a hole charge balance. The second light emitting auxiliary layer EIL2 may function to relatively improve the light emission efficiency (or green light emission efficiency) of the second light emitting layer EML2 by adjusting a hole charge balance. The third light emitting auxiliary layer EIL3 may function to relatively improve the light emission efficiency (or blue light emission efficiency) of a third light emitting layer EML3 by adjusting a hole charge balance.

The first to third light emitting layers EML1 to EML3 may be located on the first to third light emitting auxiliary layers EIL1 to EIL3, respectively. Holes transferred from the first to third anodes AE1 to AE3 and electrons transferred from a cathode CE may be respectively recombined in the first to third light emitting layers EML1 to EML3, thereby forming excitons. Light may be generated when the excitons are changed from an excited state to a ground state. The first light emitting layer EML1 may generate light of a red color. The second light emitting layer EML2 may generate light of a green color. The third light emitting layer EML3 may generate light of a blue color. Each of the first to third light emitting layers EML1 to EML3 may include an organic light emitting material generating light of a corresponding color. However, embodiments according to the present disclosure are not limited thereto. For example, each of the first to third light emitting layers EML1 to EML3 may include an inorganic light emitting material, a quantum dot, and the like.

A common layer CML may be located on the first to third light emitting layers EML1 to EML3. The common layer CML may include a buffer layer BFL, an electron transport layer ETL, the cathode CE, and a capping layer CPL.

The buffer layer BFL may be located on the first to third light emitting layers EML1 to EML3. The buffer layer BFL may be entirely provided throughout the first to third sub-pixels SP1 to SP3. The buffer layer BFL may function to control injection of electrons from the cathode CE to the first to third light emitting layers EML1 to EML3. Accordingly, holes and electrons may be uniformly injected into the first to third light emitting layers EML1 to EML3.

The electron transport layer ETL may be located on the buffer layer BFL. The electron transport layer ETL may be entirely provided throughout the first to third sub-pixels SP1 to SP3. The electron transport layer ETL may include at least one of Tris(8-hydroxyquinolinato)aluminum (Alq3), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tris(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), berylliumbis(benzoquinolin-10-olate (Bebq2), 9,10-di(naphthalene-2-yl) anthracene (ADN), or diphenyl(4-(triphenylsilyl)phenyl) phosphine oxide (TSPO1). However, embodiments according to the present disclosure are not limited thereto.

The cathode CE may be located on the electron transport layer ETL. The cathode CE may be entirely provided throughout the first to third sub-pixels SP1 to SP3. The cathode CE may be a thin metal layer having a thickness to a degree to which light emitted from the first to third light emitting layers EML1 to EML3 can be transmitted therethrough. The cathode CE may be formed of a transparent conductive material or a metal material to have a relatively thin thickness. For example, the cathode CE may include at least one of various transparent conductive materials including indium tin oxide, indium zinc oxide, indium tin zinc oxide, aluminum zinc oxide, gallium zinc oxide, zinc tin oxide, or gallium tin oxide. For example, the cathode CE may include at least one of silver (Ag), magnesium (Mg), or mixtures thereof. However, embodiments according to the present disclosure are not limited thereto.

The first to third sub-pixels SP1 to SP3 may include first to third light emitting elements LD1 to DL3, respectively. The first light emitting element LD may be configured with the first anode AE1, a portion of the hole injection layer HIL, which overlaps therewith, a portion of the hole transport layer HTL, which overlaps therewith, the first resonance auxiliary layer RIL1, the first light emitting auxiliary layer EIL1, the first light emitting layer EML1, a portion of the buffer layer BFL, which overlaps therewith, a portion of the electron transport layer ETL, which overlaps therewith, and a portion of the cathode CE, which overlaps therewith. The second light emitting element LD2 may be configured with the second anode AE2, a portion of the hole injection layer HIL, which overlaps therewith, a portion of the hole transport layer HTL, which overlaps therewith, the second resonance auxiliary layer RIL2, the second light emitting auxiliary layer EIL2, the second light emitting layer EML2, a portion of the buffer layer BFL, which overlaps therewith, a portion of the electron transport layer ETL, which overlaps therewith, and a portion of the cathode CE, which overlaps therewith. The third light emitting element LD3 may be configured with the third anode AE3, a portion of the hole injection layer HIL, which overlaps therewith, a portion of the hole transport layer HTL, which overlaps therewith, the third light emitting auxiliary layer EIL3, the third light emitting layer EML3, a portion of the buffer layer BFL, which overlaps therewith, a portion of the electron transport layer ETL, which overlaps therewith, and a portion of the cathode CE, which overlaps therewith.

The capping layer CPL may be located on the cathode CE. The capping layer CPL may be entirely provided throughout the first to third sub-pixels SP1 to SP3. The capping layer CPL may function to prevent a foreign material such as oxygen or moisture from infiltrating into the common layer CML.

According to some embodiments, the common layer CML may further include an electron injection layer located between the electron transport layer ETL and the cathode CE. The electron injection layer may be entirely provided throughout the first to third sub-pixels SP1 to SP3. The electron injection layer may include at least one of a halogenated metal such as LiF, NaCl, CsF, RbCl or RbI, a lanthanum group metal such as Yb, a metal oxide such as Li₂O or BaO, or Lithium quinolate (LiQ). However, embodiments according to the present disclosure are not limited thereto.

Several masks may be used in the deposition process of the pixel PXL. For example, the hole injection layer HIL, the hole transport layer HTL, and the common layer CML, which are entirely provided through the first to third sub-pixels SP1 to SP3, may be deposited using an open mask OM. The open mask OM may be a mask having no covering portion to entirely deposit layers. For example, the first to second resonance auxiliary layers RIL1 and RIL2, which are respectively provided in the first and second sub-pixels SP1 and SP2, may be deposited using a fine metal mask FMM. In addition, the first to third light emitting auxiliary layers EIL1 to EIL3 and the first to third light emitting layers EML1 to EML3, which are respectively provided in the first to third sub-pixels SP1 to SP3, may be deposited using the fine metal mask FMM. The fine metal mask FMM may be a mask having the covering portion to deposit layers on a specific surface.

FIG. 6 is a view of a deposition process according to some embodiments.

For convenience of description, a deposition layer DPL deposited (or overlapping) on a substrate SUB is illustrated as an example in FIG. 6. The deposition layer DPL may be any one of the first and second resonance auxiliary layers RIL1 and RIL2, the first to third light emitting auxiliary layers EIL1 to EIL3, and the first to third light emitting layers EML1 to EML3, which are shown in FIG. 5.

Referring to FIG. 6, the deposition layer DPL may be deposited using a fine metal mask FMM and a deposition source. The fine metal mask FMM means a fine mask made of a metal material. When the deposition layer DPL is the first resonance auxiliary layer RIL1 or the second resonance auxiliary layer RIL2, the deposition source may include a resonance auxiliary source constituting the first resonance auxiliary layer RIL1 or the second resonance auxiliary layer RIL2. When the deposition layer DPL is any one of the first to third light emitting auxiliary layers EIL1 to EIL3, the deposition source may include a light emitting auxiliary source constituting any one of the first to third light emitting auxiliary layers EIL1 to EIL3 When the deposition layer DPL is any one of the first to third light emitting layers EML1 to EML3, the deposition source may include a light emitting source constituting any one of the first to third light emitting layers EML1 to EML3.

As shown in FIG. 6, the deposition source may be a dynamic point source DPS which moves without stopping during the deposition process. Organic materials evaporated in the deposition source may be deposited on the substrate SUB while passing through an opening OP1 of the fine metal mask FMM. For example, when the dynamic point source DPS is located at the center, the organic materials may be mainly deposited in a deposition area DA of the substrate SUB while passing through the opening OP1 of the fine metal mask FMM at a high incident angle (e.g., 90 degrees). However, when the dynamic point source DPS is located at a side, the organic materials may pass through the opening OP1 of the fine metal mask FMM at a relatively low first incident angle θ1. The organic materials may be mainly deposited in an area, i.e., a shadow area SA except the deposition area DA of the substrate SUB due to a shadow effect. As the incident angle of the organic materials passing through the opening OP1 of the fine metal mask FMM becomes smaller, a width w1 of the deposition layer DPL deposited in the shadow area SA of the substrate SUB may increase. A distance margin between the deposition layer DPL and a component adjacent to the deposition layer DPL increases, and therefore, high-resolution deposition may be difficult.

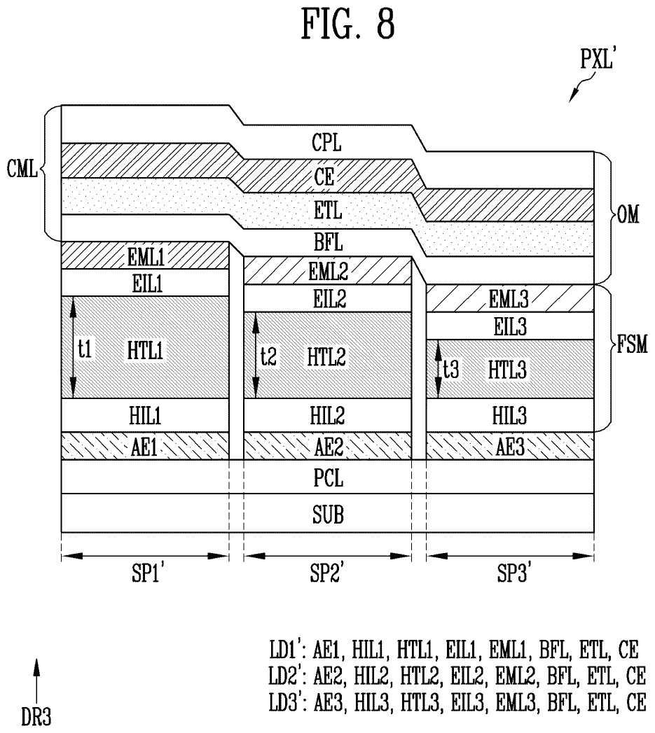

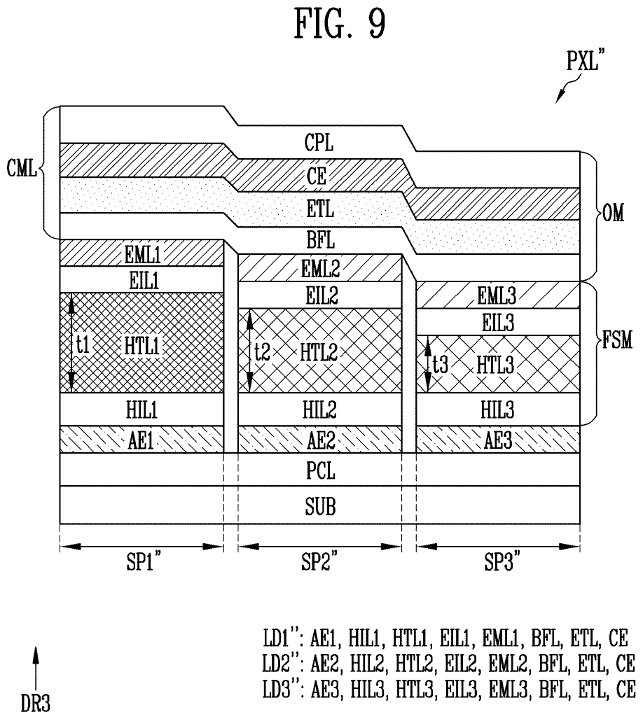

FIG. 7 is a view of a deposition process according to some embodiments. For convenience of description, a deposition layer DPL′ deposited (or overlapping) on a substrate SUB is illustrated as an example in FIG. 7. The deposition layer DPL′ may be any one of first to third hole injection layers HIL1 to HIL3, first to third hole transport layers HTL1 to HTL3, first to third light emitting auxiliary layers EIL1 to EIL3, and first to third light emitting layers EML1 to EML3, which are shown in FIGS. 8 and 9. In relation to FIG. 7, some descriptions of portions overlapping with those shown in FIG. 6 may be simplified or omitted.

Referring to FIG. 7, the deposition layer DPL′ may be deposited using a fine silicon mask FSM and a deposition source. The fine silicon mask FSM means a fine mask made of a silicon material. The fine silicon mask FSM may include an elaborately formed opening OP2. For example, a width ow2 of the opening OP2 of the fine silicon mask FSM may be smaller than a width ow1 of the opening OP1 of the fine metal mask FMM (see FIG. 6). For example, the width ow2 of the opening OP2 of the fine silicon mask FSM may be 0.5 μm or less. Therefore, the fine silicon mask FSM may be more suitable for high-resolution deposition than the fine metal mask FMM.

When the deposition layer DPL′ is any one of the first to third hole injection layers HIL1 to HIL3, the deposition source may include a hole injection source constituting any one of the first to third hole injection layers HIL1 to HIL3. When the deposition layer DPL′ is any one of the first to third hole transport layers HTL1 to HTL3, the deposition source may include a hole transport source constituting any one of the first to third hole transport layers HTL1 to HTL3. When the deposition layer DPL′ is any one of the first to third light emitting auxiliary layers EIL1 to EIL3, the deposition source may include a light emitting auxiliary source constituting any one of the first to third light emitting auxiliary layers EIL1 to EIL3. When the deposition layer DPL′ is any one of the first to third light emitting layers EML1 to EML3, the deposition source may include a light emitting source constituting any one of the first to third light emitting layers EML1 to EML3. That is, the deposition source may be changed according to a kind of the deposition layer DPL′.

As shown in FIG. 7, the deposition source may be a static point source SPS which does not move, i.e., in a standstill state during the deposition process. When the deposition source is the static point source SPS, organic materials evaporated in the deposition source may pass through the fine silicon mask FSM at a high incident angle. For example, when the static point source SPS is located in the standstill state at the center, the organic materials may be mainly deposited in a deposition area DA of a substrate SUB while passing through the opening OP2 of the fine silicon mask FSM at a relatively high second incident angle θ2. According to some embodiments, the second incident angle θ2 may be 80 to 90 degrees. When the second incident angle θ2 satisfies the above-described range, a width w2 of the deposition layer DPL′ deposited in a shadow area SA of the substrate SUB may decrease. For example, the width w2 of the deposition layer DPL′ deposited in the shadow area SA, using the fine silicon mask FSM and the static point source SPS, may be smaller than the width w1 of the deposition layer DPL deposited in the shadow area SA, using the fine metal mask FMM and the dynamic point source DPS (see FIG. 6). According to some embodiments, the width w2 of the deposition layer DPL′ deposited in the shadow area SA may be 0.2 μm or less. A distance margin between the deposition layer DPL′ and a component adjacent to the deposition layer DPL′ decreases, and thus high-resolution deposition can be readily performed.

FIG. 8 is a view of a pixel according to some embodiments.

In FIG. 8, a pixel PXL′ manufactured according to the deposition process shown in FIG. 7 is illustrated as an example. In relation to FIG. 8, some descriptions of portions overlapping with those shown in FIG. 5 may be simplified or omitted.

Referring to FIG. 8, first to third hole injection layers HIL1 to HIL3 may be located on first to third anodes AE1 to AE3, respectively. The first hole injection layer HIL1 may be included in a first sub-pixel SP1′. The second hole injection layer HIL2 may be included in a second sub-pixel SP2′. The third hole injection layer HIL3 may be included in a third sub-pixel SP3′. The first to third hole injection layers HIL1 to HIL3 may be made of the same material as the hole injection layer HIL shown in FIG. 5.

First to third hole transport layers HTL1 to HLT3 may be located on the first to third hole injection layers HIL1 to HIL3, respectively. In an example, the first to third hole transport layers HTL1 to HLT3 may be made of the same material. For example, the first to third hole transport layers HTL1 to HLT3 may be made of the same material as the hole transport layer HTL shown in FIG. 5.

According to some embodiments, thicknesses of the first to third hole transport layers HTL1 to HLT3 may be different from one another. For example, a thickness t1 of the first hole transport layer HTL1 may be 1950 to 2300 Å, a thickness t2 of the second hole transport layer HTL2 may be 1350 to 1700 Å, and a thickness t3 of the third hole transport layer HTL3 may be 1150 to 1400 Å.

According to some embodiments, the thickness t1 of the first hole transport layer HTL1 may be greater than the thickness t2 of the second hole transport layer HTL2. In addition, the thickness t2 of the second hole transport layer HTL2 may be greater than the thickness t3 of the third hole transport layer HTL3. Accordingly, each of the first and second hole transport layers HTL1 and HTL2 may function to control resonance of light of a corresponding color. For example, the first hole transport layer HTL1 may function to control resonance of light of a red color, which is generated in a first light emitting layer EML1. In addition, the second hole transport layer HTL2 may function to control resonance of light of a green color, which is generated in a second light emitting layer EML2. That is, resonance of lights of different colors may be controlled through the first and second hole transport layers HTL1 and HTL2 without any resonance auxiliary layers such as the first and second resonance auxiliary layers RIL1 and RIL2, which are shown in FIG. 5. A deposition process for forming resonance auxiliary layers such as the first and second resonance auxiliary layers RIL1 and RIL2 can be omitted, thereby relatively simplifying manufacturing processes.

According to some embodiments, a HOMO energy level of the first to third hole transport layers HTL1 to HTL3 may be −5.1 eV or higher. When the HOMO energy level of the first to third hole transport layers HTL1 to HTL3 satisfies the above-described range, holes can be stably transferred from the first to third hole injection layers HIL1 to HIL3 to the first to third hole transport layers HTL1 to HTL3, respectively.

As shown in FIG. 5, when the hole injection layer HIL and the hole transport layer HTL are entirely formed through the first to third sub-pixels SP1 to SP3, a leakage current may be generated between the first to third sub-pixels SP1 to SP3 adjacent to each other through the hole injection layer HIL and/or the hole transport layer HIL. As shown in FIG. 8, the first to third hole injection layers HIL1 to HIL3 may be spaced apart from each other, and the first to third hole transport layers HTL1 to HTL3. No leakage current is generated between the first to third sub-pixels SP1′ to SP3′ adjacent to each other, and thus the color reproducibility, reliability, and the like of the display device 100 (see FIG. 1) can be relatively improved.

First to third light emitting auxiliary layers EIL1 to EIL3 may be located on the first to third hole transport layers HTL1 to HTL3, respectively.

The first to third sub-pixels SP1′ to SP3′ may include first to third light emitting elements LD1′ to LD3′. The first light emitting element LD1′ may be configured with the first anode AE1, the first hole injection layer HIL1, the first hole transport layer HTL1, the first light emitting auxiliary layer EIL1, the first light emitting layer EML1, a portion of a buffer layer BFL, which overlaps therewith, a portion of an electron transport layer ETL, which overlaps therewith, and a portion of a cathode CE, which overlaps therewith. The second light emitting element LD2′ may be configured with the second anode AE2, the second hole injection layer HIL2, the second hole transport layer HTL2, the second light emitting auxiliary layer EIL2, the second light emitting layer EML2, a portion of the buffer layer BFL, which overlaps therewith, a portion of the electron transport layer ETL, which overlaps therewith, and a portion of the cathode CE, which overlaps therewith. The third light emitting element LD3′ may be configured with the third anode AE3, the third hole injection layer HIL3, the third hole transport layer HTL3, the third light emitting auxiliary layer EIL3, a third light emitting layer EML3, a portion of the buffer layer BFL, which overlaps therewith, a portion of the electron transport layer ETL, which overlaps therewith, and a portion of the cathode CE, which overlaps therewith.

Several masks may be used in the deposition process of the pixel PXL′. For example, a common layer CML entirely provided through the first to third sub-pixels SP1′ to SP3′ may be deposited using an open mask OM. For example, the first to third hole injection layers HIL1 to HIL3, the first to third hole transport layers HTL1 to HTL3, the first to third light emitting auxiliary layers EIL1 to EIL3, and the first to third light emitting layers EML1 to EML3, which are respectively provided in the first to third sub-pixels SP1′ to SP3′, may be deposited using a fine silicon mask FSM.

FIG. 9 is a view of a pixel according to some embodiments.

In FIG. 9, a pixel PXL″ manufactured according to the deposition process shown in FIG. 7 is illustrated as an example. In relation to FIG. 9, some descriptions of portions overlapping with those shown in FIGS. 5 and 8 may be simplified or omitted.

Referring to FIG. 9, first to third hole transport layers HTL1 to HTL3 may be made of different materials. For example, the first hole transport layer HTL1 may be made of a material suitable for controlling injection of holes injected into a first light emitting layer EML1. In addition, the second hole transport layer HTL2 may be made of a material suitable for controlling injection of holes injected into a second light emitting layer EML2. In addition, the third hole transport layer HTL3 may be made of a material suitable for controlling injection of holes injected into a third light emitting layer EML3. In other words, each of the first to third hole transport layers HTL1 to HTL3 may be made of a material suitable for controlling the light emission efficiency of each of the first to third light emitting layers EML1 to EML3, and the material is not particularly limited.

First to third sub-pixels SP1″ to SP3″ may include first to third light emitting elements LD1″ to LD3″, respectively. The first to third sub-pixels SP1″ to SP3″ may be substantially identical to the first to third light emitting elements LD1′ to LD3′ shown in FIG. 8, except that the first to third hole transport layers HTL1 to HTL3 are made of different materials.

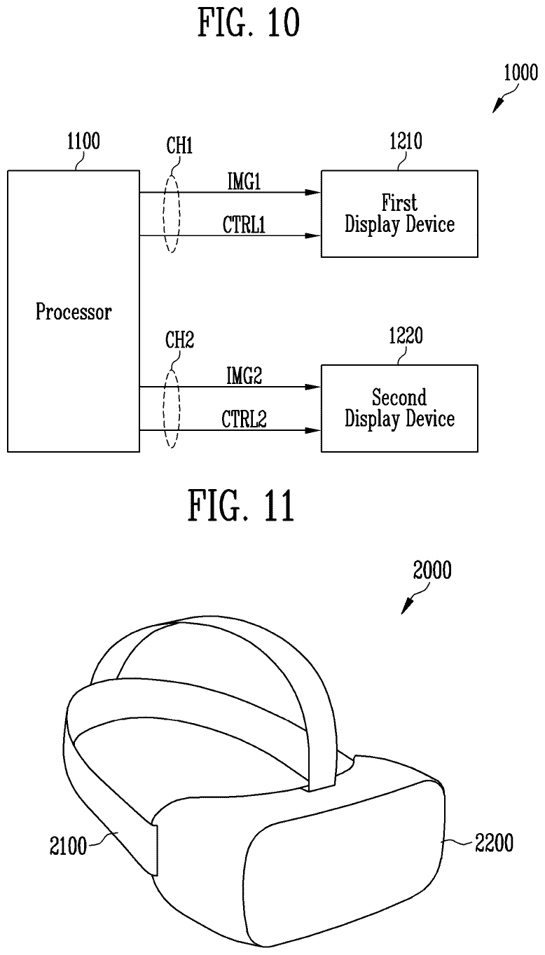

FIG. 10 is a block diagram of a display system according to some embodiments.

Referring to FIG. 10, the display system 1000 may include a processor 1100 and one or more display devices 1210 and 1220.

The processor 1100 may perform various tasks and various calculations. According to some embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 10, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, or an augmented reality (AR) device.

FIG. 11 is a perspective view of an application example of the display system of FIG. 10 according to some embodiments.

Referring to FIG. 11, the display system 1000 shown in FIG. 10 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments according to the present disclosure are not limited thereto. For example, the head mounting band 2100 may be implemented in the form of a glasses frame, a helmet or the like.

The display device accommodating case 2200 may accommodate the first and second display devices 1210 and 1220 shown in FIG. 10. The display device accommodating case 2200 may further accommodate the processor 1100 shown in FIG. 10.

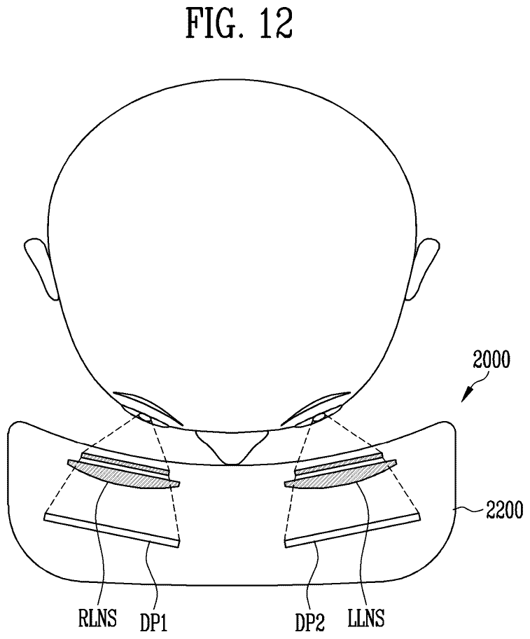

FIG. 12 is a view of a head-mounted display device of FIG. 11, which is worn by a user according to some embodiments.

Referring to FIG. 12, a first display panel DP1 of the first display device 1210 and a second display panel DP2 of the second display device 1220 may be located in the head mounted display device 2000. The head mounted display device 2000 may further include one or more lenses LLNS and RLNS.

In the display device accommodating case 2200, a right-eye lens RLNS may be located between the first display panel DP1 and a right eye of the user. In the display device accommodating case 2200, a left-eye lens LLNS may be located between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

According to some embodiments, each of the right-eye lens RLNS and the left-eye lens LLNS may include an optical lens having a pancake-shaped section. According to some embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

According to some embodiments, there can be provided a method of manufacturing a display device, which relatively reduces a process margin, and a high-resolution display device manufactured according to the method.

However, aspects and features of the present disclosure are not limited to those described above, and various other aspects and features would be understood by one of ordinary skill in the art within the spirit and scope of the present disclosure.

The embodiments described in detail above are provided to explain the present disclosure, but these embodiments according to the present disclosure are not intended to limit the scope of embodiment according to the present disclosure. It should be understood by those skilled in the art that various changes, substitutions, and alternations may be made therein without departing from the scope of the disclosure as defined by the following claims and their equivalents.

The scope of embodiments according to the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of embodiments according to the present disclosure. The embodiments may be combined to form additional embodiments.

What is claimed is:

1. A display device, comprising:
a pixel circuit layer on a substrate;
anodes on the pixel circuit layer and spaced apart from each other;
hole injection layers respectively on the anodes;
hole transport layers respectively on the hole injection layers;
light emitting layers respectively on the hole transport layers; and
a common layer on the light emitting layers.

2. The display device according to claim 1, wherein the anodes include a first anode, a second anode, and a third anode, and
wherein the hole injection layers include a first hole injection layer on the first anode, a second hole injection layer on the second anode, and a third hole injection layer on the third anode.

3. The display device according to claim 2, wherein the hole transport layers include a first hole transport layer on the first hole injection layer, a second hole transport layer on the second hole injection layer, and a third hole transport layer on the third hole injection layer.

4. The display device according to claim 3, wherein thicknesses of the first hole transport layer, the second hole transport layer, and the third hole transport layer are different from one another.

5. The display device according to claim 4, wherein a thickness of the first hole transport layer is greater than a thickness of the second hole transport layer, and the thickness of the second hole transport layer is greater than a thickness of the third hole transport layer.

6. The display device according to claim 4, wherein a thickness of the first hole transport layer is in a range of 1950 to 2300 Å, a thickness of the second hole transport layer is in a range of 1350 to 1700 Å, and a thickness of the third hole transport layer is in a range of 1150 to 1400 Å.

7. The display device according to claim 1, wherein the hole transport layers are made of a same material.

8. The display device according to claim 1, wherein the hole transport layers are made of different materials.

9. The display device according to claim 1, wherein a HOMO energy level of the hole transport layers is −5.1 eV or higher.

10. The display device according to claim 3, wherein the light emitting layers include a first light emitting layer on the first hole transport layer and configured to emit light of a first color, a second light emitting layer on the second hole transport layer and configured to emit light of a second color, and a third light emitting layer on the third hole transport layer and configured to emit light of a third color, and
wherein the first hole transport layer is configured to control resonance of the light of the first color emitted from the first light emitting layer, and the second hole transport layer is configured to control resonance of the light of the second color emitted from the second light emitting layer.

11. The display device according to claim 10, further comprising:
a first light emitting auxiliary layer between the first hole transport layer and the first light emitting layer;
a second light emitting auxiliary layer between the second hole transport layer and the second light emitting layer; and
a third light emitting auxiliary layer between the third hole transport layer and the third light emitting layer.

12. The display device according to claim 1, wherein the common layer includes:
a buffer layer on the light emitting layers;
an electron transport layer on the buffer layer;
a cathode on the electron transport layer; and
a capping layer on the cathode.

13. A method of manufacturing a display device, the method comprising:
forming anodes on a pixel circuit layer on a substrate and spaced apart from each other;
respectively forming hole injection layers on the anodes, using a fine silicon mask and a hole injection source;
respectively forming hole transport layers on the hole injection layers, using the fine silicon mask and hole transport sources;
respectively forming light emitting layers on the hole transport layers, using the fine silicon mask and light emitting sources; and
forming a common layer on the light emitting layers, using an open mask.

14. The method according to claim 13, wherein an incident angle at which the hole injection source, the hole transport sources, and the light emitting sources pass through the fine silicon mask is in a range of 80 to 90 degrees.

15. The method according to claim 14, wherein the hole injection source, the hole transport sources, and the light emitting sources are point sources in a standstill state.

16. The method according to claim 15, wherein a width of the hole injection layers, the hole transport layers, and the light emitting layers, which overlap with a shadow area of the substrate, is in a range of 0.2 μm or less.

17. The method according to claim 13, wherein a width of an opening of the fine silicon mask is in a range of 0.5 μm or less.

18. The method according to claim 13, wherein thicknesses of the hole transport layers are different from one another.

19. The method according to claim 13, wherein the hole transport sources are made of a same material.

20. The method according to claim 13, wherein the hole transport sources are made of different materials.
